(19) United States
(12) Patent Application Publication
(10) Pub. No.: US 2026/0150742 A1
(43) Pub. Date: May 28, 2026

(54) MASK AND SOLDER BALL MOUNTING DEVICE INCLUDING THE SAME

(71) Applicant: Samsung Electronics Co., Ltd., Suwon-si (KR)

(72) Inventors: Seungyeop OH, Suwon-si (KR); Taehwan KIM, Suwon-si (KR); Woojin CHOI, Suwon-si (KR); Hyeon HWANG, Suwon-si (KR)

(73) Assignee: Samsung Electronics Co., Ltd., Suwon-si (KR)

(21) Appl. No.: 19/386,835

(22) Filed: Nov. 12, 2025

(30) Foreign Application Priority Data
Nov. 22, 2024 (KR) 10-2024-0168798

(51) Int. Cl. H01L 23/00

(52) U.S. Cl. CPC H10W 72/0112; H10W 72/012; H10W 72/01204; H10W 72/01257

(57) ABSTRACT

A mask for mounting solder balls on a substrate may include a first body defining a plurality of holes penetrating from a top surface of the mask to a bottom surface of the mask, and a plurality of second bodies covering inner surfaces of the plurality of holes, a distance between center points of top surface openings of adjacent holes is greater than a distance between center points of bottom surface openings of the adjacent holes.

### CROSS-REFERENCE TO RELATED APPLICATION

This U.S. non-provisional application is based on and claims the benefit of priority under 35 U.S.C. § 119 to Korean Patent Application No. 10-2024-0168798, filed on Nov. 22, 2024, in the Korean Intellectual Property Office, the disclosure of which is incorporated by reference herein in its entirety.

### BACKGROUND

One or more example embodiments of the inventive concepts relate to a mask and a solder ball mounting device including the same, a system including the same, and/or a method of using the same, and more particularly, to a mask for mounting solder balls on a substrate, a solder ball mounting device including the same, a system including the same, and/or a method of using the same.

In recent years, the demand for portable devices in the electronics market has been rapidly increasing. As a result, there is a continuous demand for smaller and lighter electronic components embedded in these electronic products. For smaller and lighter electronic components, electronic components mounted thereon are desired and/or required to have increasingly smaller physical sizes while processing greater amounts of data with less defects.

As the electronic components become denser, the number of connection terminals is increasing. Thus, the pitch may decrease due to the increased number of connection terminals, thereby reducing the mounting reliability of solder balls on a substrate, such as a printed circuit board.

### SUMMARY

One or more example embodiments of the inventive concepts provide a mask with improved mounting reliability of solder balls, a solder ball mounting device including the same, a system including the same, and/or a method of manufacturing the same.

In addition, the example embodiments of the inventive concepts are not limited to the mentioned above, and other example embodiments of the inventive concepts may clearly be recognized or understood by a person of ordinary skill in the art.

According to at least one example embodiment of the inventive concepts, there is provided a mask for mounting solder balls on a substrate, a first body defining a plurality of holes penetrating from a top surface of the mask to a bottom surface of the mask, and a plurality of second bodies covering inner surfaces of the plurality of holes, a distance between center points of top surface openings of adjacent holes is greater than a distance between center points of bottom surface openings of the adjacent holes.

According to at least one example embodiment of the inventive concepts, there is provided a solder ball mounting device including a stage configured to support a substrate, a mask on the substrate, and a mounting device above the mask, the mask including, a top surface and a bottom surface, a first body defining a plurality of holes penetrating from the top surface of the mask to the bottom surface of the mask, and a plurality of second bodies covering inner surfaces of the plurality of holes in the first body, a distance between center points of top surface openings of adjacent holes is greater than a distance between center points of bottom surface openings of the adjacent holes, and a melting point of the first body is higher than a melting point of the plurality of second bodies.

According to at least one example embodiment of the inventive concepts, there is provided a solder ball mounting device including a stage configured to support a substrate, a mask on the substrate, the mask having a horizontal surface area greater than a horizontal surface area of the substrate, and a mounting device above the mask, the mounting device including a flux mount and a solder ball mount, the flux mount configured to hold and release at least one flux, and the solder ball mount configured to hold and release at least one solder ball, the mask including, a first body defining a plurality of holes penetrating from a top surface of the mask to a bottom surface of the mask, and a plurality of second bodies covering inner surfaces of the plurality of holes in the first body, a distance between center points of top surface openings of adjacent holes is greater than a distance between center points of bottom surface openings of the adjacent holes.

According to at least one example embodiment of the inventive concepts, there is provided a system including a meltable mask including a plurality of holes within the meltable mask, the meltable mask configured to receive at least one solder ball on at least one hole of the plurality of holes, and a mounting device configured to transfer the at least one solder ball to the meltable mask.

Some example embodiments provide that each hole of the plurality of holes includes a top opening and a bottom opening, the top opening having a larger diameter than the bottom opening.

Some example embodiments provide that the meltable mask includes at least a first material and a second material, the first material having a higher melting point than the second material.

Some example embodiments provide that for each hole of the plurality of holes, the second material covers an interior surface of an opening in the first material, the opening corresponding to the hole.

Some example embodiments provide that the mounting device is further configured to transfer at least one flux to the meltable mask, and the meltable mask is further configured to receive the flux on the at least one hole of the plurality of holes.

Some example embodiments provide that the second material is configured to be removed from the meltable mask through a reflow process.

Some example embodiments provide that the first material is configured to be removed through the reflow process.

### BRIEF DESCRIPTION OF THE DRAWINGS

Some example embodiments will be more clearly understood from the following detailed description taken in conjunction with the accompanying drawings in which:

FIG. 1 is a schematic diagram of a solder ball mounting device according to some example embodiments;

FIG. 2 is a schematic perspective view of a mask in FIG. 1 according to some example embodiments;

FIG. 3 is a schematic plan view of the mask in FIG. 1 according to some example embodiments;

FIG. 4 is a schematic bottom view of the mask in FIG. 1 according to some example embodiments;

FIG. 5 is a cross-sectional view taken along line A1-A1′ in FIG. 4 according to some example embodiments;

FIG. 6 is a schematic diagram of an embodiment of a mounting unit in FIG. 1 according to some example embodiments;

FIG. 7 is a schematic diagram of an embodiment of the mounting unit in FIG. 1 according to some example embodiments;

FIGS. 8 to 13 are schematic diagrams illustrating a method of mounting solder balls according to some example embodiments;

FIG. 14 is a schematic cross-sectional view of a mask according to some example embodiments;

FIG. 15 is a schematic cross-sectional view of a mask according to some example embodiments; and

FIG. 16 is a schematic cross-sectional view of a mask according to some example embodiments.

### DETAILED DESCRIPTION OF THE EXAMPLE EMBODIMENTS

Hereinafter, one or more example embodiments are described in detail with reference to the accompanying drawings. The same reference numerals are used for the same components in the drawings, and redundant description thereof is omitted.

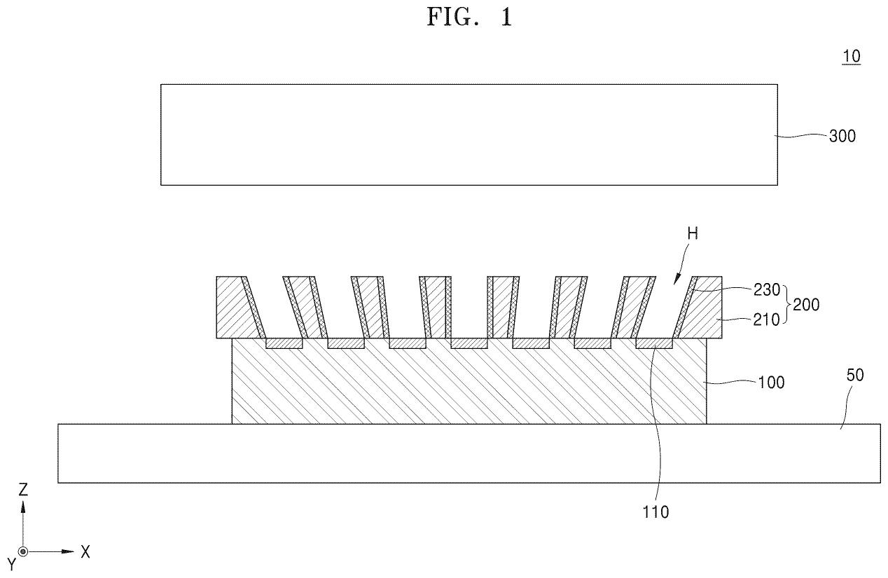

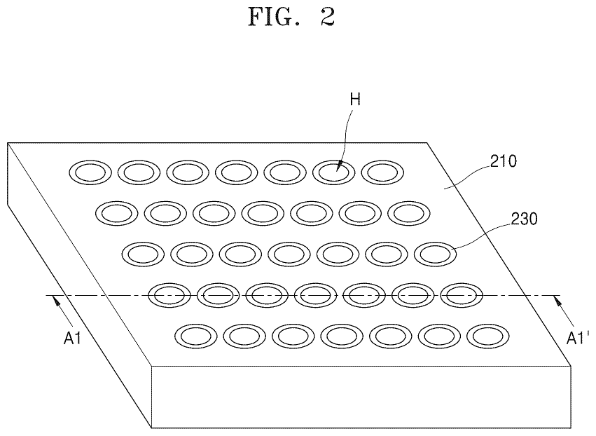

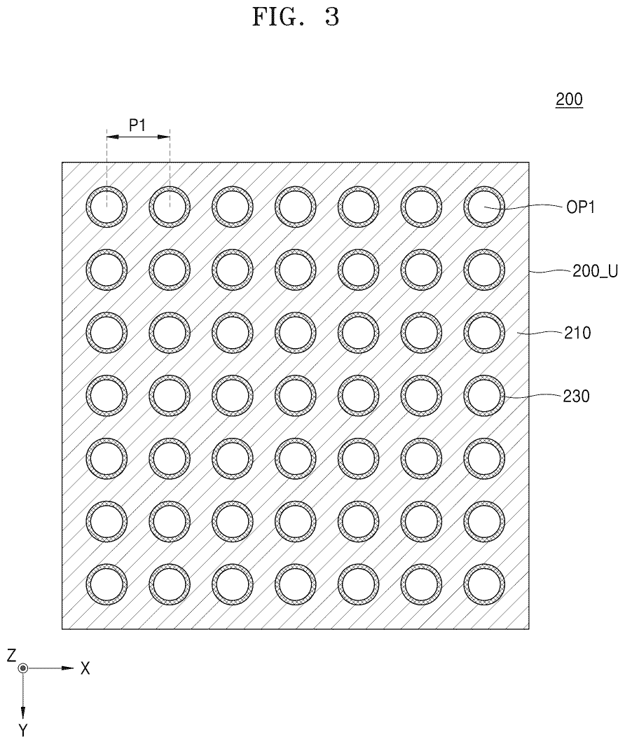

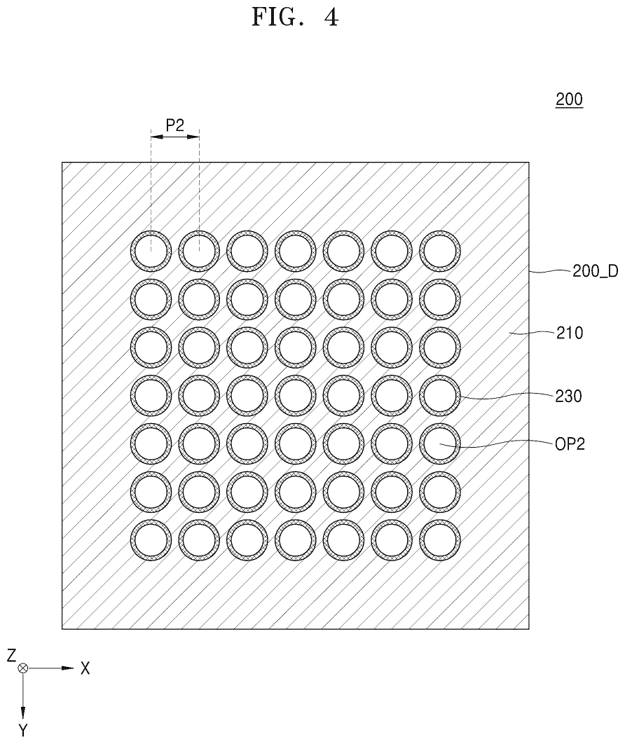

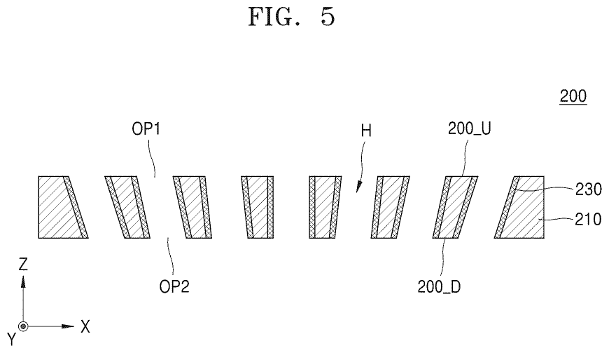

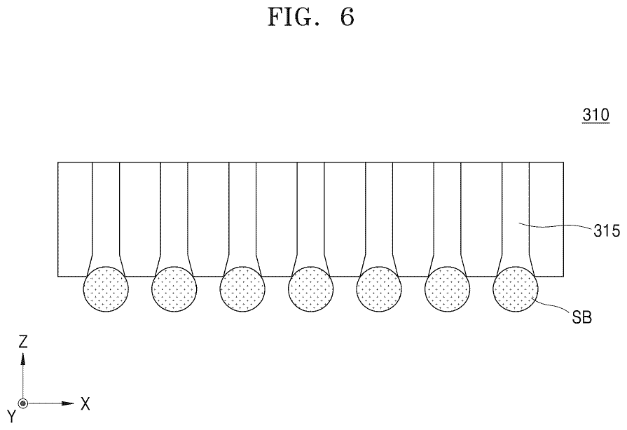

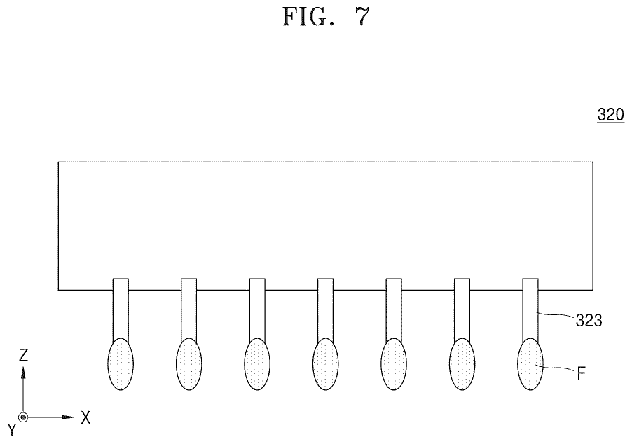

FIG. 1 is a schematic diagram of a solder ball mounting device according to some example embodiments. FIG. 2 is a schematic perspective view of a mask in FIG. 1 according to some example embodiments. FIG. 3 is a schematic plan view of the mask in FIG. 1 according to some example embodiments. FIG. 4 is a schematic bottom view of the mask in FIG. 1 according to some example embodiments. FIG. 5 is a cross-sectional view taken along line A1-A1′ in FIG. 4 according to some example embodiments. FIG. 6 is a schematic diagram of an embodiment of a mounting unit in FIG. 1 according to some example embodiments. FIG. 7 is a schematic diagram of an embodiment of the mounting unit in FIG. 1 according to some example embodiments.

Referring to FIGS. 1 to 7, a solder ball mounting device 10 may include a stage 50, a mask 200, and/or a mounting unit 300 (e.g., a mounting device, etc.), but is not limited thereto. The stage 50 may be configured to support an object on which a solder ball SB is mounted. The object on which the solder ball SB is mounted may include, for example, at least one substrate 100 (e.g., a semiconductor substrate, etc.). The object on which the solder ball SB is mounted is not limited to the substrate 100. The object may include a semiconductor device, a semiconductor chip, a semiconductor package, an interposer, a connector, a module, and the like. Hereinafter, the object on which the solder ball SB is mounted is described as the substrate 100 for the convenience of explanation. However, the object on which the solder ball SB is mounted is not limited to the substrate 100.

A top surface of the stage 50 may be flat, but is not limited thereto. In the following drawings, an X-axis direction and a Y-axis direction may be parallel to the top surface of the stage 50. The X-axis direction and the Y-axis direction may be perpendicular to each other. A Z-axis direction may be perpendicular to the X-axis direction and the Y-axis direction. In addition, a first horizontal direction, a second horizontal direction, and a vertical direction in the following drawings may be understood as follows: the first horizontal direction is the X-axis direction, the second horizontal direction is the Y-axis direction, and the vertical direction is the Z-axis direction.

The substrate 100 may be located on the top surface of the stage 50. As a substrate on which a semiconductor chip is mounted, the substrate 100 may include a ceramic substrate, a printed circuit board (PCB), an organic substrate, and the like. In addition, in some example embodiments, the substrate 100 may include a redistribution structure formed through a redistribution process, but is not limited thereto. The substrate 100 may include an insulating layer and/or wiring formed in the insulating layer, etc.

According to some example embodiments, at least one of a top surface and a bottom surface of the substrate 100 may be flat. A substrate pad 110 may be formed on at least one of the top surface and the bottom surface of the substrate 100. A plurality of substrate pads 110 may be provided. According to some example embodiments, the substrate pads 110 may be electrically connected to the wiring formed in the substrate 100. In some example embodiments, some of the substrate pads 110 may be electrically connected to the wiring formed in the substrate 100, and the others may not be connected to the wiring formed in the substrate 100. The substrate pads 110 that are not connected to the wiring may be understood as dummy pads.

The mask 200 may be located on the substrate 100. The mask 200 may have a top surface 200_U and a bottom surface 200_D. According to some example embodiments, the top surface 200_U and the bottom surface 200_D of the mask 200 may be flat, but are not limited thereto.

The mask 200 may include a first body 210 and one or more second bodies 230. The first body 210 may include and/or define a plurality of holes H extending from the top surface 200_U to the bottom surface 200_D of the mask 200, but the example embodiments are not limited thereto. The plurality of holes H may penetrate from the top surface 200_U to the bottom surface 200_D of the mask 200. Hereinafter, unless stated otherwise, the top surface 200_U and the bottom surface 200_D of the mask 200 may be understood to be the same as a top surface and a bottom surface of the first body 210, respectively. The second bodies 230 may surround surfaces of the holes H formed in the first body 210. For example, the second bodies 230 may be formed to surround side surfaces of the holes H in the first body 210. The top surface of the first body 210 may be coplanar with top surfaces of the second bodies 230. The first body 210 may be integrally formed with the second bodies 230.

According to some example embodiments, the first body 210 may have the shape of a flat plate, or in other words, the first body 210 may be flat and/or substantially flat (e.g., within +/−10%), and may include the holes H penetrating the flat plate. The second bodies 230 may surround the inner surfaces of the holes H in the first body 210, respectively. That is, the second bodies 230 may cover the inner surfaces of the first body 210, respectively, defined by the holes H in the first body 210. One or more of the second bodies 230 may have a donut shape when viewed from above in the vertical direction Z, but are not limited thereto, and for example, one or more of the second bodies 230 may have other shapes. For example, in at least one example embodiment, one or more of the second bodies 230 may have a ring shape, etc., when viewed from above in the vertical direction Z. The shape of the second bodies 230 viewed above in the vertical direction Z may vary depending on the horizontal cross-section of the holes H. For example, when the horizontal cross-section of the holes H has a rectangular shape, the second bodies 230 may have a rectangular ring shape, etc.

Each of the holes H may include a first opening OP1 coplanar with the top surface 200_U of the mask 200 and a second opening OP2 coplanar with the bottom surface 200_D of the mask 200. The first opening OP1 may face the mounting unit 300, and the second opening OP2 may face the substrate 100. The mask 200 may be located on the substrate 100, and the second opening OP2 may overlap with the substrate pad 110 in the vertical direction Z. Accordingly, the substrate pad 110 may be exposed from the mask 200 in the vertical direction Z.

According to some example embodiments, the first opening OP1 and the second opening OP2 may have the same horizontal cross-sectional area, but are not limited thereto. In the same sense, the cross-sectional area of the first opening OP1 along an X-Y plane may be the same and/or substantially the same (e.g., within +/−10%) as the cross-sectional area of the second opening OP2 along the X-Y plane. The cross-sectional area of each of the first opening OP1 and the second opening OP2 along the X-Y plane may be understood as a cross-sectional area of a figure defined by an edge of each of the first opening OP1 and the second opening OP2. In addition, the cross-sectional area of each of the first opening OP1 and the second opening OP2 along the X-Y plane may be understood to be the same as the cross-sectional area of each of the first opening OP1 and the second opening OP2 along a horizontal plane.

According to some example embodiments, the cross-section of each of the first opening OP1 and the second opening OP2 along the X-Y plane may have a circular shape. However, the shape of the cross-section of each of the first opening OP1 and the second opening OP2 along the X-Y plane is not limited thereto. For example, the cross-section of each of the first opening OP1 and the second opening OP2 may include a polygon, etc.

The plurality of holes H may each form an angle with the bottom surface 200_D of the mask 200, but the example embodiments are not limited thereto. The angles formed by the plurality of holes H with the bottom surface 200_D of the mask 200 may be different from each other. For example, among the plurality of holes H, angles formed by holes H located in a central portion of the mask 200 with the bottom surface 200_D of the mask 200 may be different from angles formed by holes H located in an outer portion of the mask 200 with the bottom surface 200_D of the mask 200, etc. The angles formed by the holes H with the bottom surface 200_D of the mask 200 may increase from the central portion to the outer portion of the mask 200, but are not limited thereto. The angle formed by the hole H with the bottom surface 200_D of the mask 200 may be understood as an angle formed by a line extending from the center of the first opening OP1 of the hole H to the center of the second opening OP2 of the hole H with the bottom surface 200_D of the mask 200, wherein the line extending from the center of the first opening OP1 to the center of the second opening OP2 may be referred to as a centerline. In addition, the angle formed by the hole H with the bottom surface 200_D of the mask 200 may be defined as 90 degrees or greater. For example, when the centerline of the hole H is inclined with respect to the bottom surface 200_D of the mask 200, the centerline and the bottom surface 200_D of the mask 200 may form an angle of A degrees less than 90 degrees and an angle of B degrees greater than 90 degrees, wherein the angle formed by the centerline of the hole H and the bottom surface 200_D of the mask 200 may be defined as B degrees. In addition, when the centerline of the hole H is perpendicular to the bottom surface 200_D of the mask 200, the angle formed by the centerline of the hole H with the bottom surface 200_D of the mask 200 may be defined as 90 degrees. Therefore, the angle formed by the hole H with the bottom surface 200_D of the mask 200 may be defined as 90 degrees or greater.

Among the plurality of holes H, the centerlines of the holes H located in the outer portion of the mask 200 may be inclined more than the centerlines of the holes H located in the central portion of the mask 200, but the example embodiments are not limited thereto. In the same sense, among the plurality of holes H, the centerlines of the holes H located in the outer portion of the mask 200 may be closer to the bottom surface 200_D of the mask 200 than the centerlines of the holes H located in the central portion of the mask 200. Referring to FIG. 5, the holes H located in the central portion of the mask 200 may form a right angle to the bottom surface 200_D of the mask 200, and the holes H located in the outer portion of the mask 200 may form an obtuse angle with the bottom surface 200_D of the mask 200, but the example embodiments are not limited thereto.

According to some example embodiments, an interval P1 (e.g., a distance, etc.) between the first openings OP1 may be greater than an interval P2 (e.g., a distance) between the second openings OP2, but are not limited thereto. In other words, the interval P1 refers to a distance between center points of two adjacent first openings OP1 (e.g., the top surfaces of the holes H), and the interval P2 refers to a distance between center points of two adjacent second openings OP2 (e.g., the bottom surfaces of the holes H). Since the holes H in the outer portion of the mask 200 form an obtuse angle with the bottom surface 200_D of the mask 200, the interval P1 between the first openings OP1 may be greater than the interval P2 between the second openings OP2, but the example embodiments are not limited thereto, and for example, the interval P1 may be the same as the interval P2, or the interval P1 may be less than the interval P2.

The first body 210 and the second bodies 230 may include a material that is melted by heat (e.g., removed by heat, etc.). Specifically, the first body 210 and the second bodies 230 may include a material that is melted by heat generated during a reflow process. According to some example embodiments, the melting point of the first body 210 may be higher than that of the second bodies 230. In some example embodiments, the boiling point of the first body 210 may be higher than that of the second bodies 230, but is not limited thereto. In some example embodiments, the melting point of the first body 210 may be higher than boiling point of the second bodies 230, but is not limited thereto.

According to some example embodiments, the melting point of the first body 210 may range from approximately 215 degrees Celsius (C.) to approximately 235 degrees C., and the melting point of the second bodies 230 may range from approximately 140 degrees C. to approximately 160 degrees C., but the example embodiments are not limited thereto, and materials with other temperature ranges may be used.

The mounting unit 300 may be located above the mask 200. The mounting unit 300 may face the mask 200 in the vertical direction Z. The mounting unit 300 may overlap with the mask 200 in the vertical direction Z. The mounting unit 300 may move in the horizontal direction X and/or Y and the vertical direction Z and may rotate about the vertical direction Z.

According to some example embodiments, the mounting unit 300 may include a solder ball unit 310 (e.g., solder ball mount, etc.) as shown in FIG. 6, and/or a flux unit 320 (e.g., a flux mount, etc.) as shown in FIG. 7, but is not limited thereto. The solder ball unit 310 may be configured to adhere to and/or hold the solder ball SB through an adhesion member 315. For example, the solder ball SB may include, but is not limited to, a solder bump including a low melting point metal, for example, tin (Sn) and/or a Sn alloy. The solder ball SB may have various shapes, such as a land, a ball, a pin, a pillar, etc. In this specification, the solder ball SB is described as having a ball shape, but is not limited thereto.

A plurality of adhesion members 315 may be formed. The adhesion members 315 may fix and/or hold the solder balls SB. According to some example embodiments, the adhesion members 315 may fix and/or hold the solder balls SB using vacuum suction (e.g., negative pressure), but the example embodiments are not limited thereto. The solder balls SB may be located to overlap with the first openings OP1 of the mask 200 in the vertical direction Z by the solder ball unit 310. The solder balls SB may be released from the adhesion members 315, e.g., by releasing the vacuum suction, and dropped onto the top surface 200_U of the mask 200. At this time, the solder balls SB may be dropped onto the first openings OP1 of the mask 200.

The cross-sectional area of the solder ball SB along the X-Y plane may be greater than the cross-sectional area of a figure defined by the outer edge of the second body 230 along the X-Y plane, but is not limited thereto. In other words, the cross-sectional area of the solder ball SB along the X-Y plane may be greater than the cross-sectional area of the second body 230 along the X-Y plane. The cross-sectional area of the solder ball SB along the X-Y plane may be less than the cross-sectional area of a figure defined by the edge of the hole H in the first body 210 along the X-Y plane, but is not limited thereto. In other words, the cross-sectional area of the solder ball SB along the X-Y plane may be less than the cross-sectional area of the first body 210 along the X-Y plane. Accordingly, when the second bodies 230 are melted during the reflow process or the like, the solder balls SB may move into the holes H in the first body 210. The cross-sectional area of the solder ball SB along the X-Y plane may be understood to be the same as the horizontal cross-sectional area of the solder ball SB.

The flux unit 320 may be configured to fix and/or hold a flux F and may drop the flux F onto the mask 200. The flux F may be fixed by and/or held by a pin 323 and may be released from the pin 323 to fall onto the mask 200. Specifically, the flux F may fall onto the first opening OP1 of the mask 200.

As a material used during a process of attaching the solder ball SB to the substrate pad 110 of the substrate 100, the flux F may include a material that removes an oxide layer from a surface of the substrate pad 110 and reduces and/or prevents generation of a new oxide layer during a soldering process.

In the solder ball mounting device 10 according to at least one example embodiment of the inventive concepts, the flux F and the solder ball SB may not be directly dropped from the mounting unit 300 onto the substrate 100 but may be mounted on the substrate 100 through the mask 200.

The plurality of holes H may be formed in the mask 200 of the solder ball mounting device 10. Each of the plurality of holes H may have the first opening OP1 facing the mounting unit 300 and the second opening OP2 located on the substrate 100. In addition, since the interval P1 between the first openings OP1 is greater than the interval P2 between the second openings OP2, the flux F and the solder ball SB may be more easily mounted on the substrate pad 110.

Specifically, the interval between the substrate pads 110 located in the substrate 100 may decrease as the semiconductor device is miniaturized. Accordingly, in the existing solder ball mounting device, the interval between the fluxes F and the interval between solder balls SB dropped onto the substrate pads 110 may also be reduced. The fluxes F may be in contact with each other and the solder balls SB may be in contact with each other in both cases where the fluxes F and solder balls SB are each fixed to the mounting unit 300 and where the fluxes F and solder balls SB are each dropped onto the substrate 100. This may cause a short (e.g., an electrical short circuit, etc.) between the fluxes F and between the solder balls SB. In addition, as the interval between the fluxes F and the interval between the solder balls SB decrease, the fluxes F and solder balls SB may be mounted away from the substrate pads 110.

However, since the interval P1 between the first openings OP1 is greater than the interval P2 between the second openings OP2 in the solder ball mounting device 10 according to one or more example embodiments of the inventive concepts, the fluxes F and the solder balls SB may be more easily mounted on the substrate pads 110 even when the pitch between the substrate pads 110 is reduced.

In addition, the first body 210 and the second bodies 230 of the mask 200 may be all removed by heat generated during the reflow process. When the first body 210 is first melted by heat, the fluxes F and the solder balls SB may move onto the substrate pads 110. The solder balls SB may be mounted on the substrate pads 110 as the second bodies 230 are melted by heat. Thus, the substrate pads 110 may be more easily bonded to the solder balls SB, respectively, thereby improving bonding reliability.

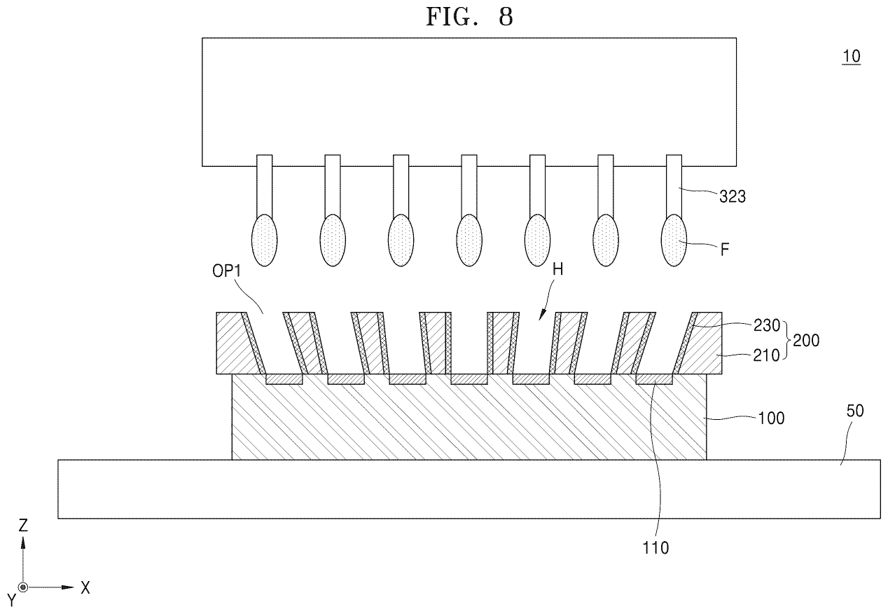

FIGS. 8 to 13 are schematic diagrams illustrating a method of mounting solder balls according to some example embodiments. Hereinafter, redundant description made with reference to FIGS. 1 to 7 are omitted, and differences are mainly described.

Referring to FIG. 8, the substrate 100 may be located on the stage 50 such that the substrate pads 110 face upward, and the flux unit 320 (e.g., flux device, etc.) may be located above the substrate 100. The flux unit 320 may be located above the substrate 100 with the one or more fluxes F fixed by the pins 323, and the one or more fluxes F may be located to face the first openings OP1 of the mask 200.

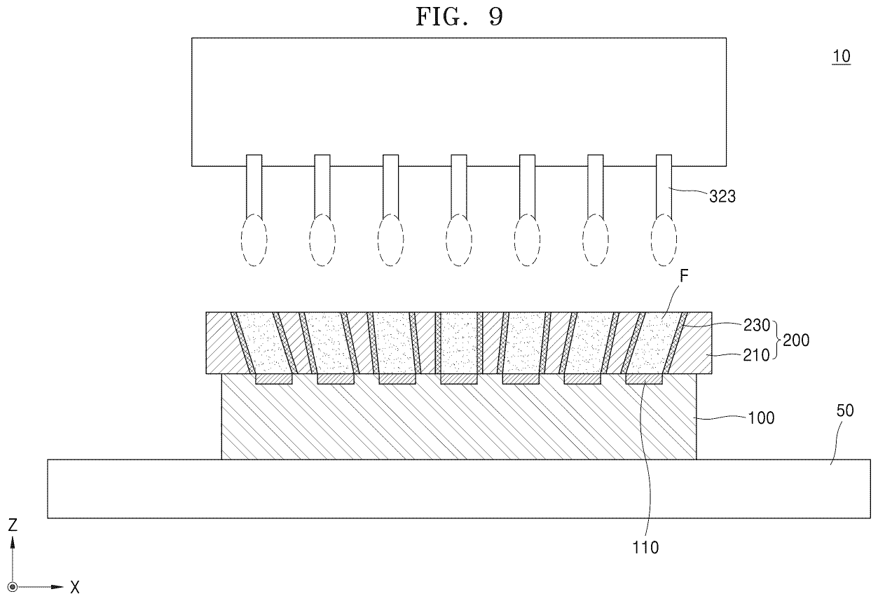

Referring to FIG. 9, the fluxes F may be released from the pins 323 and dropped onto the first openings OP1. The fluxes F may enter into the holes H through the first openings OP1. According to some example embodiments, the fluxes F may fill the holes H. However, in some example embodiments, one or more of the fluxes F may only fill up the holes H to a certain height, or in other words, the fluxes F may not completely fill the entire volume of one or more of the holes H.

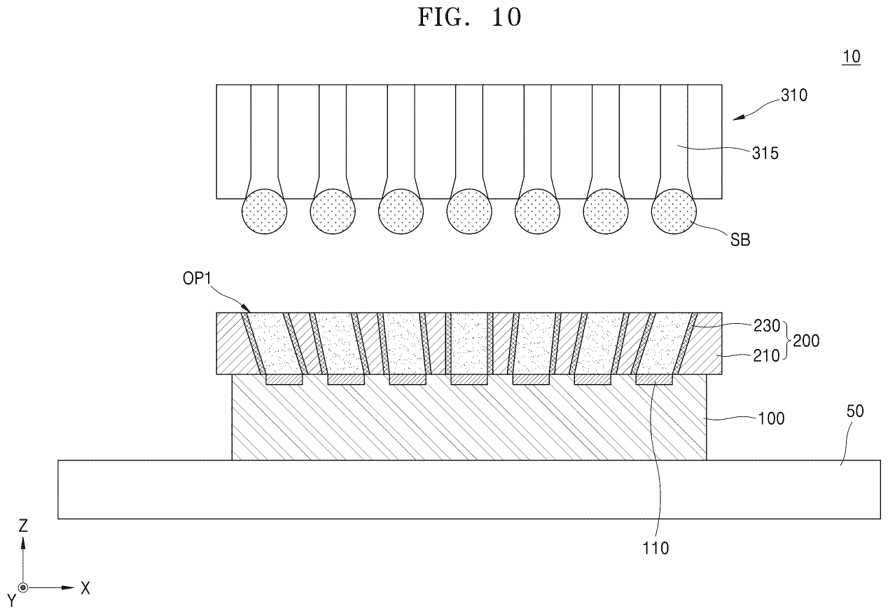

Referring to FIG. 10, the solder ball unit 310 may be located above the substrate 100. The solder balls SB may be located above the substrate 100 while being fixed by the adhesion members 315, but are not limited thereto. The solder balls SB may be located to face the first openings OP1.

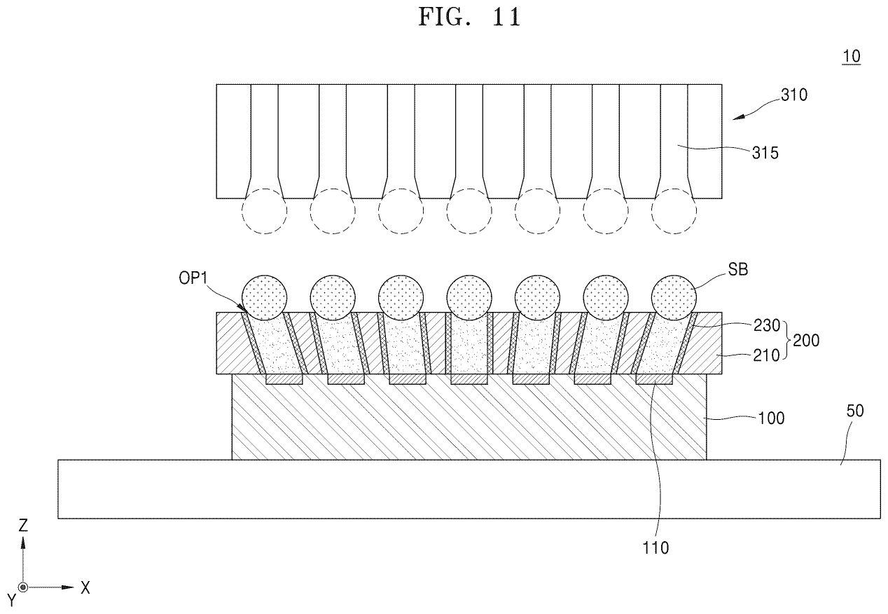

Referring to FIG. 11, the solder balls SB may be released from the adhesion members 315 and dropped onto the first openings OP1. For example, the solder balls SB may be dropped onto the fluxes F, but the example embodiments are not limited thereto. Since the horizontal cross-sectional area of the solder ball SB is greater than the horizontal cross-sectional area of the figure defined by the edge of the second body 230, the solder ball SB may come in contact with the second body 230. Consequently, one or more of the solder balls SB may not enter into one or more of the holes H.

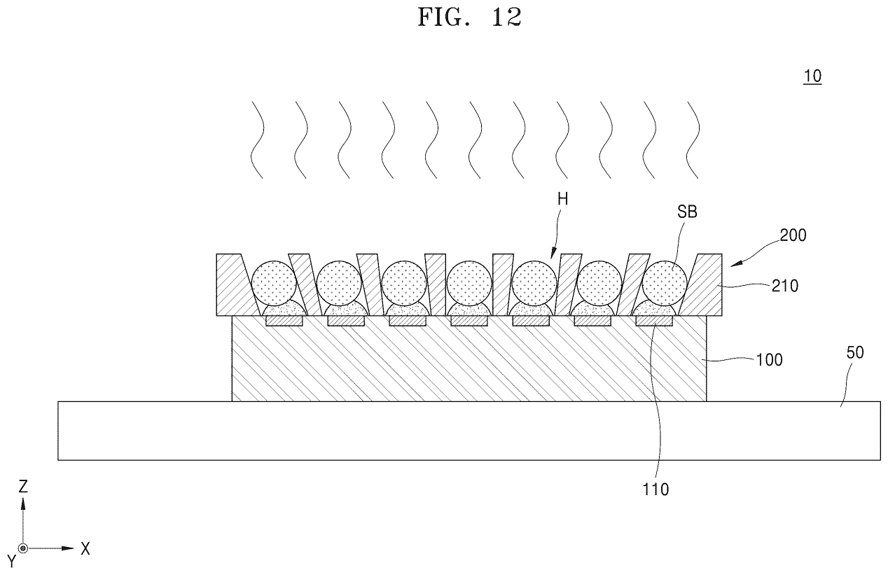

Referring to FIG. 12, the solder ball unit 310 of FIG. 11 is removed, and the reflow process is performed on the substrate 100 and the mask 200. The reflow process may be performed while the substrate 100 and the mask 200 pass through an oven at a desired temperature and/or temperature range, for example temperatures of approximately 50 degrees C. to approximately 235 degrees C., but the example embodiments are not limited thereto.

FIG. 12 illustrates a case where the substrate 100 and the mask 200 are exposed to a temperature range of approximately 140 degrees C. to approximately 160 degrees C. through the reflow process, but the example embodiments are not limited thereto. The second bodies 230 may be melted and removed. The shape of the fluxes F may be deformed by the heat of the oven and may aggregate on the substrate pads 110. The solder balls SB may enter into the holes H as the second bodies 230 are removed. The solder balls SB may be located on fluxes F. The solder balls SB may be closer to the substrate pads 110 by moving along the spaces created by the removal of the second bodies 230. Since the melting point of the first body 210 is higher than that of the second bodies 230, the first body 210 may not be melted.

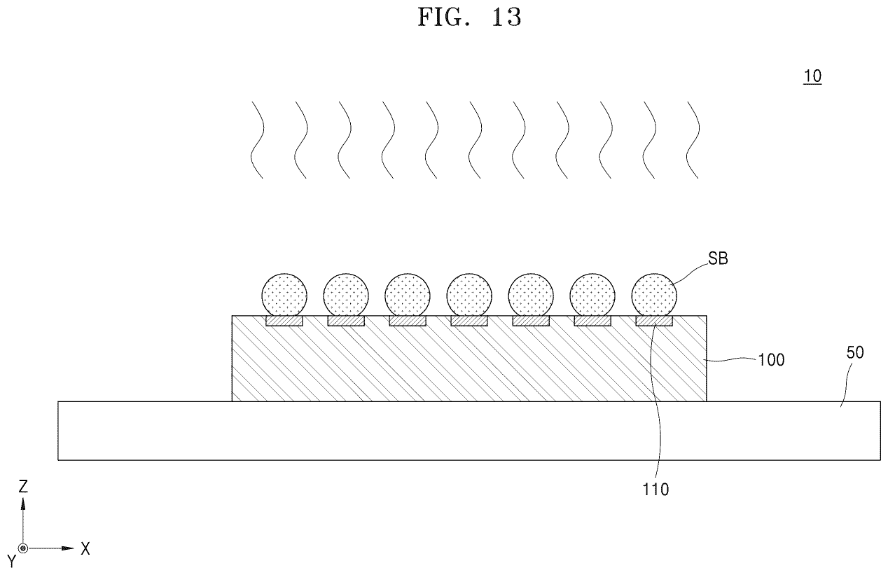

Referring to FIG. 13, through the reflow process, the substrate 100 and the mask 200 (e.g., see FIG. 12) may be exposed to a temperature range of approximately 215 degrees C. to approximately 235 degrees C. to remove the first body 210 (e.g., see FIG. 11), but the example embodiments are not limited thereto. As the first body 210 is removed, the mask 200 (e.g., see FIG. 12) may be completely removed.

The solder balls SB may be mounted on the substrate pads 110 as the mask 200 (e.g., see FIG. 12) is removed (e.g., melted, etc.). The fluxes F may be removed by heat or only some of the fluxes F may remain.

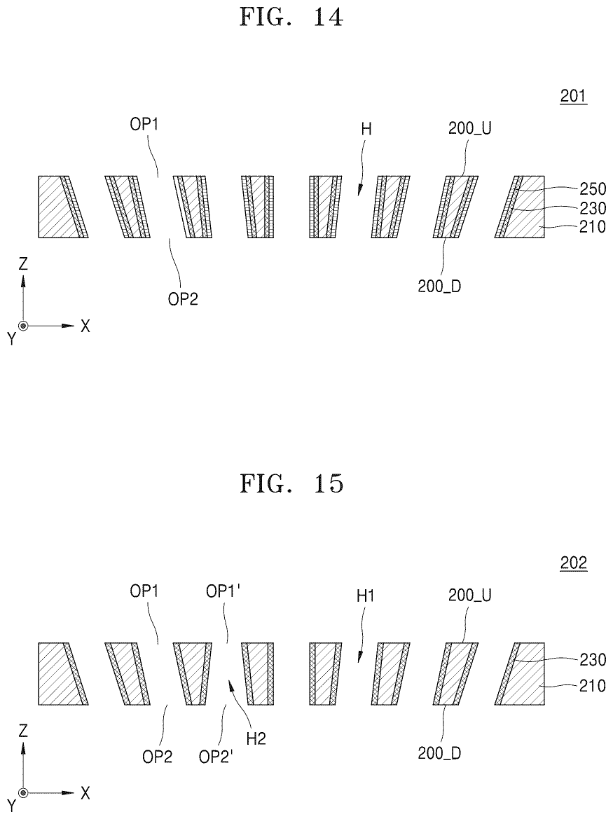

FIG. 14 is a schematic cross-sectional view of a mask according to some example embodiments. Hereinafter, redundant description between the mask 200 described with reference to FIGS. 1 to 7 and a mask 201 described with reference to FIG. 14 are omitted, and differences are mainly described.

Referring to FIG. 14, the mask 201 may have a top surface 200_U and a bottom surface 200_D. According to some example embodiments, the top surface 200_U and the bottom surface 200_D of the mask 201 may be flat, but are not limited thereto. The mask 201 may include a first body 210, one or more second bodies 230, and one or more third bodies 250, but is not limited thereto, and for example, the mask 201 may include four or more bodies, etc. The first body 210 may include a plurality of holes H extending from the top surface 200_U to the bottom surface 200_D of the mask 201. The plurality of holes H may penetrate from the top surface 200_U to the bottom surface 200_D of the mask 201. The second bodies 230 may surround the surfaces of the holes H formed in the first body 210. For example, the second bodies 230 may be formed to surround the side surfaces of the holes H in the first body 210. The second bodies 230 may surround the inner surfaces of the holes H in the first body 210. The third bodies 250 may be formed to surround the side surfaces of the second bodies 230. The third bodies 250 may surround the inner surfaces of the holes H in the second bodies 230, respectively.

Each of the plurality of holes H may include a first opening OP1 coplanar with the top surface 200_U of the mask 201, and a second opening OP2 coplanar with the bottom surface 200_D of the mask 201.

According to some example embodiments, the first opening OP1 and the second opening OP2 may have the same horizontal cross-sectional area, but the example embodiments are not limited thereto. According to some example embodiments, the cross-section of each of the first opening OP1 and the second opening OP2 along the X-Y plane may have a circular shape. However, the shape of the cross-section of each of the first opening OP1 and/or the second opening OP2 along the X-Y plane is not limited thereto. The cross-section of each of the first opening OP1 and/or the second opening OP2 may include a polygon shape and/or other shape. The plurality of holes H may be formed at angles to the bottom surface 200_D of the mask 201, but are not limited thereto. The angles formed by the plurality of holes H with the bottom surface 200_D of the mask 201 may be different from each other. For example, among the plurality of holes H, angles formed by holes H located in the central portion of the mask 201 with the bottom surface 200_D of the mask 201 may be different from angles formed by holes H located in the outer portion of the mask 201 with the bottom surface 200_D of the mask 201, etc. The angles formed by the holes H with the bottom surface 200_D of the mask 201 may increase from the central portion to the outer portion of the mask 201, but are not limited thereto.

According to some example embodiments, the interval P1 between the first openings OP1 may be greater than the interval P2 between the second openings OP2, but the example embodiments are not limited thereto. Since the holes H in the outer portion of the mask 201 form an obtuse angle with the bottom surface 200_D of the mask 201, the interval P1 between the first openings OP1 may be greater than the interval P2 between the second openings OP2, etc.

The first body 210, the second bodies 230, and/or the third bodies 250 may include materials that are melted by heat. Specifically, the first body 210, the second bodies 230, and the third bodies 250 may include materials that are melted by heat generated during the reflow process. According to some example embodiments, the melting point of the first body 210 may be higher than that of the second bodies 230, but the example embodiments are not limited thereto. The melting point of the second bodies 230 may be higher than that of the third bodies 250, but the example embodiments are not limited thereto. In some example embodiments, the boiling point of the first body 210 may be higher than that of the second bodies 230, but the example embodiments are not limited thereto. The boiling point of the second bodies 230 may be higher than that of the third bodies 250, but the example embodiments are not limited thereto.

The first body 210, the second bodies 230, and the third bodies 250 may all disappear and/or be removed by heat generated through the reflow process. According to some example embodiments, the melting point of the first body 210 may be in a range of approximately 215 degrees C. to approximately 235 degrees C., the melting point of the second bodies 230 may be in a range of approximately 140 degrees C. to approximately 160 degrees C., and the melting point of the third bodies 250 may be in a range of approximately 70 degrees to approximately 90 degrees, but the example embodiments are not limited thereto, and other materials with other melting points and/or boiling points may be used.

Since the mask 201, according to some example embodiments of the inventive concepts, includes the first body 210, the second bodies 230, and the third bodies 250 having different melting points, the solder balls SB (e.g., see FIG. 10) may be more easily and/or more accurately moved and mounted on the substrate pads 110 along the holes H.

FIG. 15 is a schematic cross-sectional view of a mask according to some example embodiments. Hereinafter, redundant description between the mask 200 described with reference to FIGS. 1 to 7 and a mask 202 described with reference to FIG. 15 are omitted, and differences are mainly described.

Referring to FIG. 15, the mask 202 may have a top surface 200_U and a bottom surface 200_D. According to some example embodiments, the top surface 200_U and the bottom surface 200_D of the mask 202 may be flat, but are not limited thereto. The mask 202 may include a first body 210 and one or more second bodies 230. The first body 210 may include a plurality of holes H1 and H2 extending from the top surface 200_U to the bottom surface 200_D of the mask 202. The plurality of holes H1 and H2 may penetrate from the top surface 200_U to the bottom surface 200_D of the mask 202. The second bodies 230 may surround the surfaces of the holes H1 and H2 formed in the first body 210. For example, the second bodies 230 may be formed to surround the side surfaces of the holes H1 and H2 in the first body 210. The second bodies 230 may surround the inner surfaces of the holes H1 and H2 in the first body 210.

Each of the plurality of holes H1 and H2 may include first openings OP1 and OP1′ that are coplanar with the top surface 200_U of the mask 202, and second openings OP2 and OP2′ that are coplanar with the bottom surface 200_D of the mask 202, respectively.

According to some example embodiments, the cross-section of each of the first openings OP1 and OP1′ and the second openings OP2 and OP2′ along the X-Y plane may have a circular shape. However, the shape of the cross-section of each of the first openings OP1 and OP1′ and the second openings OP2 and OP2′ along the X-Y plane are not limited thereto. For example, the cross-section of each of the first openings OP1 and OP1′ and the second openings OP2 and OP2′ may include a polygon shape and/or other shapes.

The holes H1 and H2 may respectively include a first hole H1 and a second hole H2. Since the first hole H1 is the same and/or substantially the same (e.g., within +/−10%) as that described with reference to FIGS. 1 to 7, the description thereof is omitted.

The second hole H2 may include the first opening OP1′ and the second opening OP2′. The horizontal cross-sectional area of the first opening OP1′ may be less than the horizontal cross-sectional area of the second opening OP2′. The horizontal width of the first opening OP1′ may be less than the horizontal width of the second opening OP2′. That is, the horizontal width of the second opening OP2′ may be greater than the horizontal width of the first opening OP1′. The cross-section of the second hole H2 along the X-Z plane may have a tapered shape in which the horizontal width thereof increases as the vertical level decreases. In the same sense, the vertical cross-section of the second hole H2 may have a tapered shape in which the horizontal width thereof increases as the vertical level decreases.

Since the second opening OP2′ of the second hole H2 has a greater horizontal width than the first opening OP1′ thereof, the mask 202 according to some example embodiments of the inventive concepts may be closer to the solder ball SB mounted on the substrate pad 110 (e.g., see FIG. 1) through the first hole H1 adjacent to the second hole H2 when the solder ball SB (e.g., see FIG. 10) is mounted on the substrate pad 110 (e.g., see FIG. 1) through the second hole H2. Subsequently, when the first body 210 disappears through the reflow process, a short (e.g., an electrical short circuit) between the solder ball SB mounted on the substrate pad 110 (e.g., see FIG. 1) through the second hole H2 and the solder ball SB mounted on the substrate pad 110 (e.g., see FIG. 1) through the first hole H1 adjacent to the second hole H2 may be generated and/or intentionally generated. The substrate pads 110 (e.g., see FIG. 1) bonded to the solder balls SB through the first hole H1 and the second hole H2 may include dummy pads that are not connected to the wiring in the substrate 100 (e.g., see FIG. 1).

By generating and/or intentionally causing a short between the solder ball SB mounted on the substrate pad 110 through the second hole H2 and the solder ball SB mounted on the substrate pad 110 (e.g., see FIG. 1) through the first hole H1 adjacent to the second hole H2, the shorted solder balls may function as structural supports, thereby improving the structural reliability of the substrate, the semiconductor package, and the like.

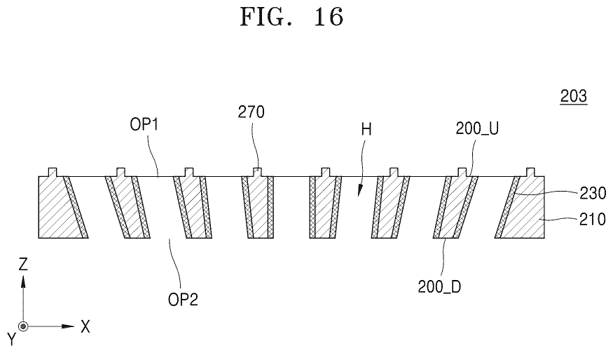

FIG. 16 is a schematic cross-sectional view of a mask according to some example embodiments. Hereinafter, redundant description between the mask 200 described with reference to FIGS. 1 to 7 and a mask 203 described with reference to FIG. 16 are omitted, and differences are mainly described.

Referring to FIG. 16, the mask 203 may have a top surface 200_U and a bottom surface 200_D. According to some example embodiments, the top surface 200_U and the bottom surface 200_D of the mask 203 may be flat, but are not limited thereto. The mask 203 may include a first body 210 and one or more second bodies 230, but is not limited thereto. The first body 210 may include a plurality of holes H extending from the top surface 200_U to the bottom surface 200_D of the mask 203. The plurality of holes H may penetrate from the top surface 200_U to the bottom surface 200_D of the mask 203. The second bodies 230 may surround the surfaces of the holes H formed in the first body 210. For example, the second bodies 230 may be formed to surround the side surfaces of the holes H in the first body 210. The second bodies 230 may surround the inner surfaces of the holes H in the first body 210.

Each of the plurality of holes H may include a first opening OP1 coplanar with the top surface 200_U of the mask 203 and a second opening OP2 coplanar with the bottom surface 200_D of the mask 203.

According to some example embodiments, the cross-section of each of the first opening OP1 and the second opening OP2 along the X-Y plane may have a circular shape. However, the shape of the cross-section of each of the first opening OP1 and the second opening OP2 along the X-Y plane is not limited thereto. The cross-section of each of the first opening OP1 and the second opening OP2 may include a polygon and/or other shapes.

The plurality of holes H may be formed at angles to the bottom surface 200_D of the mask 203, but the example embodiments are not limited thereto. The angles formed by the plurality of holes H with the bottom surface 200_D of the mask 203 may be different from each other. For example, among the plurality of holes H, the angles formed by holes H located in the central portion of the mask 203 with the bottom surface 200_D of the mask 203 may be different from angles formed by holes H located in the outer portion of the mask 203 with the bottom surface 200_D of the mask 203, etc. The angles formed by the holes H with the bottom surface 200_D of the mask 203 may increase from the central portion to the outer portion of the mask 203, but are not limited thereto.

According to some example embodiments, the interval P1 between the first openings OP1 may be greater than the interval P2 between the second openings OP2, but the example embodiments are not limited thereto. Since the holes H in the outer portion of the mask 203 form an obtuse angle with the bottom surface 200_D of the mask 203, the interval P1 between the first openings OP1 may be greater than the interval P2 between the second openings OP2, but are not limited thereto.

Protrusions 270 may be formed on a top surface of the first body 210. The protrusions 270 may extend in the vertical direction Z. The mask 203 may guide the solder balls SB into the holes H even when the solder balls SB (e.g., see FIG. 10) dropped through the protrusions 270 and fall onto the top surface 200_U of the mask 203, instead of falling through the holes H. Thus, the mounting reliability of the solder balls SB may be improved.

While the inventive concepts have been particularly shown and described with reference to some example embodiments thereof, it will be understood that various changes in form and details may be made therein without departing from the spirit and scope of the following claims.

What is claimed is:

1. A mask for mounting solder balls on a substrate, the mask comprising:
a first body defining a plurality of holes penetrating from a top surface of the mask to a bottom surface of the mask; and
a plurality of second bodies covering inner surfaces of the plurality of holes,
a distance between center points of top surface openings of adjacent holes is greater than a distance between center points of bottom surface openings of the adjacent holes.

2. The mask of claim 1, wherein a melting point of the first body is higher than a melting point of the plurality of second bodies.

3. The mask of claim 2, wherein a boiling point of the first body is higher than a boiling point of the plurality of second bodies.

4. The mask of claim 1, wherein
a horizontal cross-sectional area of at least one solder ball is greater than a horizontal cross-sectional area of the top surface opening of one hole of the plurality of holes; and
the horizontal cross-sectional area of the at least one solder ball is less than a horizontal cross-sectional area of the bottom surface opening of one hole of the plurality of holes.

5. The mask of claim 1, wherein, among the plurality of holes, a centerline of at least one hole located in a central portion of the first body is inclined further toward the bottom surface of the mask than a centerline of at least one hole located in an outer portion of the first body.

6. The mask of claim 1, further comprising:
a plurality of third bodies covering side surfaces of the plurality of second bodies.

7. The mask of claim 6, wherein the plurality of third bodies have a melting point lower than a melting point of the plurality of second bodies.

8. The mask of claim 1, wherein a plurality of protrusions extending upward in a vertical direction are on a top surface of the first body.

9. The mask of claim 1, wherein a horizontal cross-sectional area of an opening on the top surface of the mask is substantially the same as a horizontal cross-sectional area of an opening on the bottom surface of the mask.

10. The mask of claim 1, wherein
the plurality of holes includes at least a first hole and a second hole;
a horizontal width of a first opening of the first hole is the same as a horizontal width of a second opening of the first hole, the first opening of the first hole corresponding to the top of the first hole, and the second opening of the first hole corresponding to the bottom of the second hole; and
a horizontal width of a second opening of the second hole is greater than a horizontal width of a first opening of the second hole, the first opening of the second hole corresponding to the top of the first hole, and the second opening of the second hole corresponding to the bottom of the second hole.

11. A solder ball mounting device, comprising:
a stage configured to support a substrate;
a mask on the substrate; and
a mounting device above the mask,
the mask including,
a top surface and a bottom surface,
a first body defining a plurality of holes penetrating from the top surface of the mask to the bottom surface of the mask, and
a plurality of second bodies covering inner surfaces of the plurality of holes in the first body,
a distance between center points of top surface openings of adjacent holes is greater than a distance between center points of bottom surface openings of the adjacent holes, and
a melting point of the first body is higher than a melting point of the plurality of second bodies.

12. The solder ball mounting device of claim 11, wherein the mounting device comprises:
at least one pin configured to hold and release at least one flux.

13. The solder ball mounting device of claim 11, wherein the mounting device comprises:
at least one adhesion member configured to hold and release at least one solder ball.

14. The solder ball mounting device of claim 11, wherein one or more holes of the plurality of holes in an outer portion of the first body are more inclined toward a bottom surface of the first body than one or more holes of the plurality of holes in a central portion of the first body.

15. The solder ball mounting device of claim 11, further comprising:
a plurality of third bodies covering inner surfaces the plurality of second bodies.

16. The solder ball mounting device of claim 11, wherein
a melting point of the first body is in a range of approximately 215 degrees Celsius to approximately 235 degrees Celsius; and
a melting point of the plurality of second bodies is in a range of approximately 140 degrees Celsius to approximately 160 degrees Celsius.

17. The solder ball mounting device of claim 11, further comprising: a plurality of protrusions extending upward in a vertical direction on a top surface of the first body.

18. A solder ball mounting device, comprising:
a stage configured to support a substrate;
a mask on the substrate, the mask having a horizontal surface area greater than a horizontal surface area of the substrate; and
a mounting device above the mask, the mounting device including a flux mount and a solder ball mount, the flux mount configured to hold and release at least one flux, and the solder ball mount configured to hold and release at least one solder ball,
the mask including,
a first body defining a plurality of holes penetrating from a top surface of the mask to a bottom surface of the mask, and
a plurality of second bodies covering inner surfaces of the plurality of holes in the first body,
a distance between center points of top surface openings of adjacent holes is greater than a distance between center points of bottom surface openings of the adjacent holes,
one or more holes of the plurality of holes in an outer portion of the first body are more inclined toward the bottom surface of the first body than one or more holes of the plurality of holes in a central portion of the first body,
a melting point of the first body is higher than a melting point of the plurality of second bodies, and
a horizontal cross-sectional area of the solder ball is greater than a horizontal cross-sectional area of one second body of the plurality of second bodies, and the horizontal cross-sectional area of the solder ball is less than a horizontal cross-sectional area of one hole defined in the first body.

19. The solder ball mounting device of claim 18, further comprising:
a plurality of third bodies covering side surfaces of the plurality of second bodies.

20. The solder ball mounting device of claim 18, wherein the plurality of holes comprises:
at least a first hole and a second hole,
a horizontal width of a top surface opening of the first hole is the same as a horizontal width of a bottom surface opening of the first hole, and
a horizontal width of a bottom surface opening of the second hole is greater than a horizontal width of the top surface opening of the second hole.
